(19) United States
(12) Patent Application Publication
(10) Pub. No.: US 2025/0364064 A1
(43) Pub. Date: Nov. 27, 2025

(54) STORAGE DEVICE AND OPERATING METHOD OF THE STORAGE DEVICE

(71) Applicant: SK hynix Inc., Icheon-si Gyeonggi-do (KR)

(72) Inventor: Byoung Sung YOU, Icheon-si Gyeonggi-do (KR)

(73) Assignee: SK hynix Inc., Icheon-si Gyeonggi-do (KR)

(21) Appl. No.: 19/019,819

(22) Filed: Jan. 14, 2025

(30) Foreign Application Priority Data
May 24, 2024 (KR) 10-2024-0067895

(51) Int. Cl. G11C 16/34; G11C 16/26

(52) U.S. Cl. CPC G11C 16/349; G11C 16/26; G11C 16/3404

(57) ABSTRACT

A memory device including a memory block, a cell counter, and a health information manager. The memory block includes a plurality of select transistors connected to a plurality of select lines and a plurality of memory cells connected to a plurality of word lines. The cell counter counts a number of degraded select transistors which exceed a normal threshold voltage distribution width among the plurality of select transistors, based on a cell current of the plurality of select transistors, and generates cell count information including the number of the degraded select transistors. The health information manager generates read reclaim information indicating whether the memory block is a read reclaim target according to a remaining read count of the memory block and a result obtained by comparing the remaining read count with a plurality of threshold read counts, based on the cell count information.

### CROSS-REFERENCE TO RELATED APPLICATION

The present application claims priority under 35 U.S.C. § 119(a) to Korean patent application number 10-2024-0067895 filed on May 24, 2024, in the Korean Intellectual Property Office, the entire disclosure of which application is incorporated by reference herein.

### BACKGROUND

### 1. Technical Field

The present disclosure generally relates to an electronic device, and more particularly, to a storage device and an operating method of the storage device.

### 2. Related Art

A storage device may store data under the control of a host device such as a computer or a smartphone. The storage device may include a memory device in which data is stored and a memory controller which controls the memory device. The memory device is classified into a volatile memory device and a nonvolatile memory device.

The memory device may include a plurality of memory blocks. The memory device may predict a read count lifespan of a memory block, based on threshold voltage distributions of memory cells included in the memory block. The memory device may calculate a threshold voltage distribution of memory cells, based on a cell current of the memory cells, and perform a read reclaim operation at a necessary time, based on a remaining read count of the memory block, which is predicted according to a calculation result. The memory device performs the read reclaim operation at the necessary time, thereby improving the reliability of the memory block.

### SUMMARY

In accordance with an embodiment of the present disclosure, there is provided a memory device including: a memory block including a plurality of select transistors and a plurality of memory cells, the plurality of select transistors connected to a plurality of select lines and the plurality of memory cells connected to a plurality of word lines; a cell counter configured to count a number of degraded select transistors, from the plurality of select transistors, which exceed a normal threshold voltage distribution width, based on a cell current of the plurality of select transistors, and generate cell count information including the number of the degraded select transistors; and a health information manager configured to generate read reclaim information indicating whether the memory block is a read reclaim target according to a remaining read count of the memory block and a result obtained by comparing the remaining read count with a plurality of threshold read counts, based on the cell count information.

In accordance with an embodiment of the present disclosure, there is provided a storage device including: a memory device including a memory block including a plurality of select transistors connected to a plurality of select lines and a plurality of memory cells connected to a plurality of word lines; and a memory controller configured to provide the memory device with a health monitoring command for checking degraded select transistors which exceed a normal threshold voltage distribution width among the plurality of select transistors, receive, from the memory device, read reclaim information indicating whether the memory block is a read reclaim target, and control the memory device to perform a read reclaim operation on the memory block, based on the read reclaim information, wherein the memory device counts a number of the degraded select transistors, based on a cell current of the plurality of select transistors in response to the health monitoring command, calculates a remaining read count of the memory block, based on the number of the degraded select transistors, and generates the read reclaim information according to a result obtained by comparing the remaining read count with a plurality of threshold read counts.

### BRIEF DESCRIPTION OF THE DRAWINGS

Examples of embodiments will now be described hereinafter with reference to the accompanying drawings; however, they may be embodied in different forms and should not be construed as limited to the embodiments set forth herein.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a diagram illustrating a storage device in accordance with an embodiment of the present disclosure.

FIG. 2 is a diagram illustrating a memory device in accordance with an embodiment of the present disclosure.

FIG. 3 is a diagram illustrating a structure of a memory block in accordance with an embodiment of the present disclosure.

FIG. 4 is a diagram illustrating a two-dimensional section of a memory block in accordance with an embodiment of the present disclosure.

FIG. 5 is a diagram illustrating a program ratio of a memory block in accordance with an embodiment of the present disclosure.

FIG. 6 is a diagram illustrating a threshold voltage distribution of memory cells in accordance with an embodiment of the present disclosure.

FIG. 7 is a diagram illustrating a process of generating health monitoring information in accordance with an embodiment of the present disclosure.

FIG. 8 is a diagram illustrating an embodiment of the process of generating the health monitoring information, which is shown in FIG. 7.

FIG. 9 is a diagram illustrating a health monitoring operation and health monitoring information in accordance with an embodiment of the present disclosure.

FIG. 10 is a flowchart illustrating an interface command of the memory device in accordance with an embodiment of the present disclosure.

FIG. 11 is a flowchart illustrating an operation of the memory device in accordance with an embodiment of the present disclosure.

### DETAILED DESCRIPTION

The specific structural or functional description disclosed herein is merely illustrative for the purpose of describing embodiments according to the concept of the present disclosure. The embodiments according to the concept of the present disclosure can be implemented in various forms, and cannot be construed as limited to the embodiments set forth herein.

Various embodiments provide a storage device for predicting a remaining lifespan of a memory block, based on a cell current of select transistors, and performing a read reclaim operation, based to the remaining lifespan, and an operating method of the storage device.

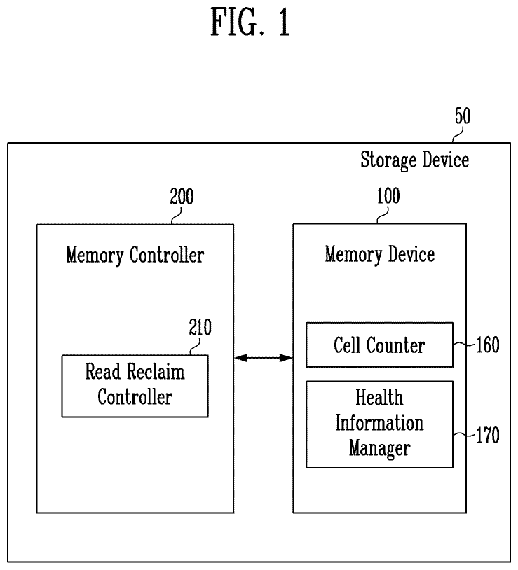

FIG. 1 is a diagram illustrating a storage device in accordance with an embodiment of the present disclosure.

Referring to FIG. 1, the storage device 50 may include a memory device 100 and a memory controller 200 which controls an operation of the memory device 100.

The memory device 100 may store data. The memory device 100 may operate under the control of the memory controller 200. The memory device 100 may include memory blocks each including a plurality of memory cells which store data.

The memory device 100 may receive a command and an address from the memory controller 200, and access an area selected by the address in a memory cell array. That is, the memory device 100 may perform an operation instructed by the command on the area selected by the address. For example, the memory device 100 may perform a write operation (program operation), a read operation, and an erase operation. In the program operation, the memory device 100 may program data in the area selected by the address. In the read operation, the memory device 100 may read data stored in the area selected by the address. In the erase operation, the memory device 100 may erase data stored in the area selected by the address.

The memory controller 200 may control overall operations of the storage device 50.

When power is applied to the data storage device 50, the memory controller 200 may execute firmware (FW). When the memory device 100 is a flash memory device, the memory controller 200 may execute firmware such as a Flash Translation Layer (FTL) for controlling communication between a host and the memory device 100.

The memory controller 200 may control the memory device 100 to perform a program operation, a read operation, an erase operation, or the like. In the program operation, the memory controller 200 may provide the memory device 100 with a write command, a physical block address, and data. In the read operation, the memory controller 200 may provide the memory device 100 with a read command and a physical block address. In the erase operation, the memory controller 200 may provide the memory device 100 with an erase command and a physical block address.

In an embodiment, the memory controller 200 may autonomously generate a command, an address, and data, regardless of any request from the host, and transmit the command, the address, and the data to the memory device 100. For example, the memory controller 200 may provide the memory device 100 with a command, an address, and data, which are used to perform background operations such as a program operation for wear leveling and a program operation for garbage collection.

In an embodiment, the controller 200 may include a read reclaim controller 210. The read reclaim controller 210 may control the memory device 100 to perform a read reclaim operation on a memory block included in the memory device 100. The read reclaim operation may be an operation of moving data stored in a memory block to another memory block to prevent or mitigate read fail from occurring due to read disturbance when a read count as a number of times a read operation on the memory block is performed is a certain reference value or more.

The read reclaim controller 210 may provide the memory device 100 with a health monitoring command for checking degraded memory cells which get out of a normal threshold voltage distribution among memory cells included in the memory block. The memory cells may include select transistors. The memory device 100 may generate read reclaim information indicating whether the memory block is a read reclaim target and store the read reclaim information in a status register, in response to the health monitoring command. The memory device 100 may copy data stored in the memory block that is the read reclaim target to another memory block.

The read reclaim controller 210 may provide a health monitoring information request command to the memory device 100. The memory device 100 may provide the read reclaim controller 210 with the health monitoring information including the read reclaim information in response to the health monitoring information request command.

In an embodiment, the memory device 100 may include a cell counter 160 and a health information manager 170.

The cell counter 160 may count a number of degraded memory cells which get out of a normal threshold voltage distribution, based on a cell current of memory cells, which is measured in a read operation. The cell counter 160 may generate cell count information including the number of degraded memory cells.

The health information manager 170 may calculate a remaining read count of a memory block, based on the cell count information. Specifically, the health information manager 170 may calculate the remaining read count, using the cell count information, a reference cell count corresponding to the cell current, and a function predetermined through a test in a manufacturing process. The health information manager 170 may generate read reclaim information indicating whether the memory block is a read reclaim target according to a result obtained by comparing the remaining read count of the memory block with a plurality of threshold read counts.

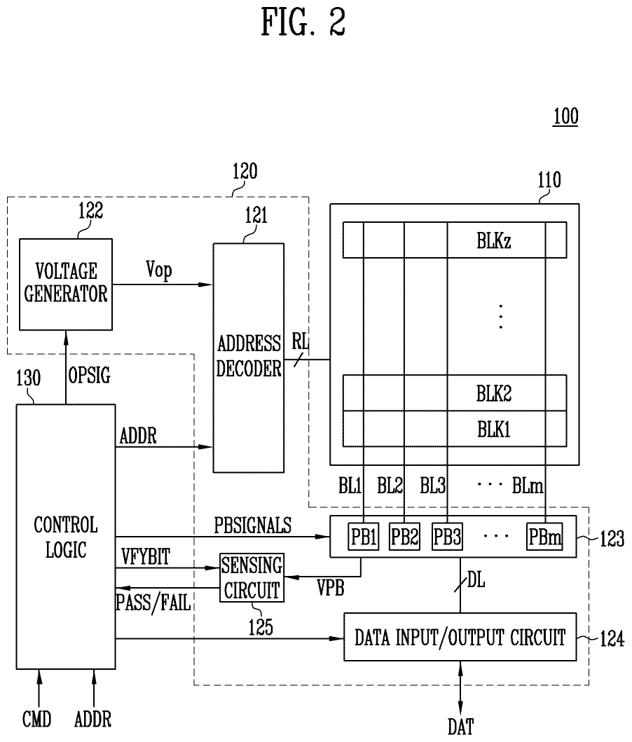

FIG. 2 is a diagram illustrating a memory device in accordance with an embodiment of the present disclosure.

Referring to FIG. 2, the memory device 100 may include a memory cell array 110, a peripheral circuit 120, and a control logic 130.

The memory cell array 110 may include a plurality of memory blocks BLK1 to BLKz. The plurality of memory blocks BLK1 to BLKz may be connected to an address decoder 121 through row lines RL. The plurality of memory blocks BLK1 to BLKz may be connected to a read/write circuit 123 through bit lines BL1 to BLm. Each of the plurality of memory blocks BLK1 to BLKz may include a plurality of memory cells.

The peripheral circuit 120 may include the address decoder 121, a voltage generator 122, the read/write circuit 123, a data input/output circuit 124, and a sensing circuit 125.

The peripheral circuit 120 may drive the memory cell array 110. For example, the peripheral circuit 120 may drive the memory cell array 110 to perform a program operation, a read operation, and an erase operation.

The address decoder 121 may be connected to the memory cell array 110 through the row lines RL. The row lines RL may include drain select lines, word lines, source select lines, and a common source line.

The address decoder 121 may operate under the control of the control logic 130. The address decoder 121 may receive an address ADDR from the control logic 130.

The address decoder 121 may decode a block address in the received address ADDR. The address decoder 121 may select at least one memory block among the memory blocks BLK1 to BLKz according to the decoded block address. The address decoder 121 may decode a row address in the received address ADDR. The address decoder 121 may select at least one word line of the selected memory block by applying voltages supplied from the voltage generator 122 to at least one word line WL according to the decoded row address.

In a program operation, the address decoder 121 may apply a program voltage to the selected word line, and apply a pass voltage having a level lower than a level of the program voltage to unselected word lines. In a program verify operation, the address decoder 121 may apply a verify voltage to the selected word line, and apply a verify pass voltage having a level higher than a level of the verify voltage to the unselected word lines.

In a read operation, the address decoder 121 may apply a read voltage to the selected word line, and apply a read pass voltage having a level higher than a level of the read voltage to the unselected word lines.

In accordance with an embodiment of the present disclosure, an erase operation of the memory device 100 may be performed in units of memory blocks. An address ADDR input to the memory device 100 in the erase operation may include a block address. The address decoder 121 may decodes a block address, and select one memory block according to the decoded block address. In an erase operation, the address decoder 121 may apply a ground voltage to the word lines of the selected memory block.

In accordance with an embodiment of the present disclosure, the address decoder 121 may decode a column address in the received address ADDR. The decoded column address may be transferred to the read/write circuit 123. For example, the address decoder 121 may include components such as a row decoder, a column decoder, and an address buffer.

The voltage generator 122 may generate a plurality of operating voltages Vop by using an external power voltage supplied to the memory device 100. The voltage generator 122 may operate under the control of the control logic 130.

In an embodiment, the voltage generator 122 may generate an internal power voltage by regulating the external power voltage. The internal power voltage generated by the voltage generator 122 may be used as an operating voltage of the memory device 100.

In an embodiment, the voltage generator 122 may generate a plurality of operating voltages Vop by using the external power voltage or the internal power voltage. The voltage generator 122 may generate various voltages required in the memory device 100. For example, the voltage generator 122 may generate a plurality of erase voltages, a plurality of program voltages, a plurality of pass voltages, a plurality of select read voltages, and a plurality of unselect read voltages.

In order to generate a plurality of operating voltages Vop having various voltage levels, the voltage generator 122 may include a plurality of camping capacitors which receive the internal power voltage. The voltage generator 122 may generate the plurality of operating voltages Vop by selectively enabling the plurality of pumping capacitors under the control of the control logic 150.

The plurality of generated operating voltages Vop may be supplied to the memory cell array 110 by the address decoder 121.

The read/write circuit 123 may include a plurality of page buffers PB1 to PBm. The page buffers PB1 to PBm may be connected to the memory cell array 110 respectively through a plurality of bit lines BL1 to BLm. The plurality of page buffers PB1 to PBm may operate under the control of the control logic 130.

The plurality of page buffers PB1 to PBm may communicate data DAT with the data input/output circuit 124. In programming, the plurality of page buffers PB1 to PBm may receive data DAT to be stored through the data input/output circuit 124 and data lines DL.

In a program operation, the plurality of page buffers PB1 to PBm may transfer, as the data DAT to be stored, data DAT received through the data input/output circuit 124 to selected memory cells through the bit lines BL1 to BLm when a program voltage is applied to the selected word line. Memory cells of a selected page may be programmed according to the transferred data DAT. A memory cell connected to a bit line through which a program allow voltage (e.g., a ground voltage) is applied may have an increased threshold voltage. A threshold voltage of a memory cell connected to a bit line through which a program inhibit voltage (e.g., a power voltage) is applied may be maintained. In a program verify operation, the plurality of page buffers PB1 to PBm may read data DAT stored in the selected memory cells from the memory cells through the bit lines BL1 to BLm.

In a read operation, the read/write circuit 123 may read data DAT from memory cells of a selected page through the bit lines BL, and store the read data DAT in the plurality of page buffers PB1 to PBm.

In an erase operation, the read/write circuit 123 may float the plurality of bit lines BL1 to BLm. In an embodiment, the read/write circuit 123 may include a column select circuit.

The data input/output circuit 124 may be connected to the plurality of page buffers PB1 to PBm through the data lines DL. The data input/output circuit 124 may operate under the control of the control logic 130.

The data input/output circuit 124 may include a plurality of input/output buffers (not shown) which receive input data DAT. In a program operation, the data input/output circuit 124 may receive data DAT to be stored from an external controller (not shown). In a read operation, the data input/output circuit 124 may output, to the external controller, data DAT transferred from the plurality of page buffers PB1 to PBm included in the read/write circuit 123.

In a read operation or verify operation, the sensing circuit 125 may generate a reference current in response to an allow bit VRYBIT generated by the control logic 130, and output a pass or fail signal PASS/FAIL to the control logic 130 by comparing a sensing voltage VPB received from the read/write circuit 123 with a reference voltage generated by the reference current.

The control logic 130 may be connected to the address decoder 121, the voltage generator 122, the read/write circuit 123, the data input/output circuit 124, and the sensing circuit 125. The control logic 130 may control a general operation of the memory device 100. The control logic 130 may operate in response to a command CMD transferred from an external device.

The control logic 130 may control the peripheral circuit 120 by generating several signals in response to a command CMD and an address ADDR. For example, the control logic 130 may generate the operation signal OPSIG, the row address, a read/write circuit control signal PBSIGNALS, and the allow bit VRYBIT in response to the command CMD and the address ADDR. The control logic 130 may output the operation signal OPSIG to the voltage generator 122, output the row address to the address decoder 121, output the read/write circuit control signal PBSIGNALS to the read/write circuit 123, and output the allow bit VRYBIT to the sensing circuit 125. Also, the control logic 130 may determine whether the verify operation has passed or failed in response to the pass or fail signal PASS/FAIL output by the sensing circuit 125.

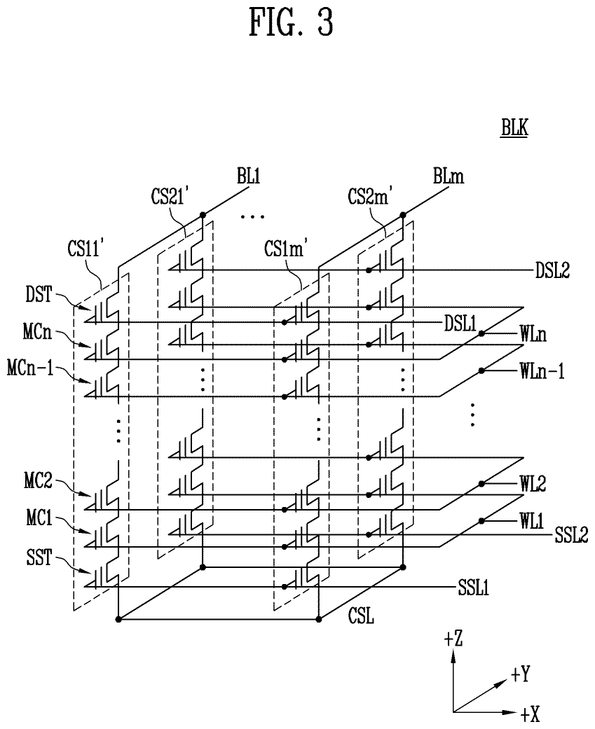

FIG. 3 is a diagram illustrating a structure of a memory block in accordance with an embodiment of the present disclosure.

Referring to FIG. 3, FIG. 3 is a circuit diagram illustrating another embodiment of any one memory block BLK among the memory blocks BLK1 to BLKz shown in FIG. 2.

Referring to FIG. 3, a memory block BLK may include a plurality of cell strings CS11′ to CS1m′ and CS21′ to CS2m′. Each of the plurality of cell strings CS11′ to CS1m′ and CS21′ to CS2m′ may extend along a +Z direction. Each of the plurality of cell strings CS11′ to CS1m′ and CS21′ to CS2m′ may include at least one source select transistor SST, first to nth memory cells MC1 to MCn, and at least one drain select transistor DST, which are stacked above a substrate (not shown) at a lower portion of the memory block BLK.

In an embodiment, one memory block may include a plurality of sub-blocks. One sub-block may include cell strings arranged in an ‘I’ shape on one column.

A source select transistor SST of each cell string may be connected between a common source line CSL and memory cells MC1 to MCn. Source select transistors of cell strings arranged on the same row may be connected to the same source select line. Source select transistors of cell strings CS11′ to CS1m′ arranged on a first row may be connected to a first source select line SSL1. Source select transistors of cell strings CS21′ to CS2m′ arranged on a second row may be connected to a second source select line SSL2. In another embodiment, the source select transistors of the cell strings CS11′ to CS1m′ and CS21′ to CS2m′ may be commonly connected to one source select line.

First to nth memory cells MC1 to MCn of each cell strings may be connected in series between the source select transistor SST and the drain select transistor DST. Gates of the first to nth memory cells MC1 to MCn may be connected to first to nth word lines WL1 to WLn, respectively.

A drain select transistor DST of each cell string may be connected between a corresponding bit line and the memory cells MC1 to MCn. Drain select transistors of cell strings arranged in a row direction may be connected to a drain select line extending in the row direction. Drain select transistors of the cell strings CS11′ to CS1m′ of the first row may be connected to a first drain select line DSL1. Drain select transistors of the cell strings CS21′ to CS2m′ of the second row may be connected to a second drain select line DSL2.

In another embodiment, even bit lines and odd bit lines may be provided instead of first to mth bit lines BL1 to BLm. In addition, even-numbered cell strings among the cell strings CS11′ to CS1m′ and CS21′ to CS2m′ arranged in the row direction may be connected to the even bit lines, respectively, and odd-numbered cell strings among the cell strings CS11′ to CS1m′ and CS21′ to CS2m′ arranged in the row direction may be connected to the odd bit lines, respectively.

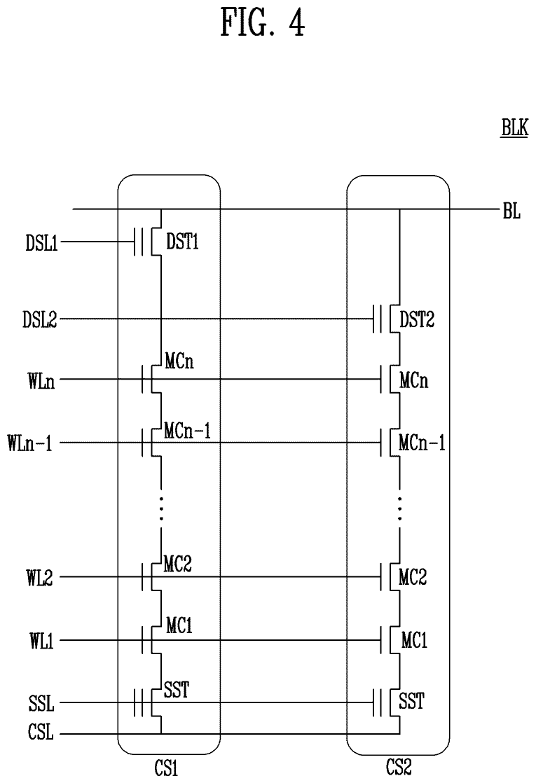

FIG. 4 is a diagram illustrating a two-dimensional section of a memory block in accordance with an embodiment of the present disclosure.

Referring to FIG. 4, a memory block BLK may include a first cell string CS1 and a second cell string CS2.

The first cell string CS1 may include a first drain select transistor DST1, a plurality of memory cells MC1 to MCn, and a source select transistor SST, which are connected in series between a bit line BL and a common source line CSL.

The second cell string CS2 may include a second drain select transistor DST2, a plurality of memory cells MC1 to MCn, and a source select transistor SST, which are connected in series between the bit line BL and the common source line CSL.

The first drain select transistor DST1 among the plurality of drain select transistors DST1 and DST2 included in the memory block BLK may be connected to a first drain select line DSL1, and the second drain select transistor DST2 among the plurality of drain select transistors DST1 and DST2 included in the memory block BLK may be connected to a second drain select line DSL2. The plurality of memory cells MC1 to MCn included in the memory block BLK may be connected to a plurality of word lines WL1 to WLn. The plurality of source select transistors SST included in the memory block BLK may be connected to a source select line SSL.

In FIG. 4, as compared with the cell strings CS11′ and CS21′ of the memory block described with reference to FIG. 3, since the same signal is applied to the first source select line SSL1 and the second source select line SSL2, the first source select line SSL1 and the second source select line SSL2 may be replaced with one source select line SSL to be illustrated in the first and second cell strings CS1 and CS2.

In order to check a threshold voltage distribution of the first drain select transistor DST1, a read operation of applying a read voltage to the first drain select line DSL1, applying a ground voltage to the second drain select line DSL2, and applying a pass voltage to the plurality of word lines WL1 to WLn and the source select line SSL may be performed.

In order to check a threshold voltage distribution of the second drain select transistor DST2, a read operation of applying a read voltage to the second drain select line DSL2, applying the ground voltage to the first drain select line DSL2, and applying the pass voltage to the plurality of word lines WL1 to WLn and the source select line SSL may be performed.

In order to check a threshold voltage distribution of the source select transistor SST, a read operation of applying a read voltage to the source select line SSL and applying the pass voltage to the plurality of word lines WL1 to WLn and the source select line SSL may be performed.

In order to check a threshold voltage distribution of the plurality of memory cells MC1 to MCn, a read operation of applying a read voltage to the plurality of word lines WL1 to WLn and applying the pass voltage to the first and second drain select lines DSL1 and DSL2 and the source select line SSL may be performed. A result obtained by checking the threshold voltage distribution of the plurality of memory cells MC1 to MCn may be used to calculate a program ratio of the memory block BLK.

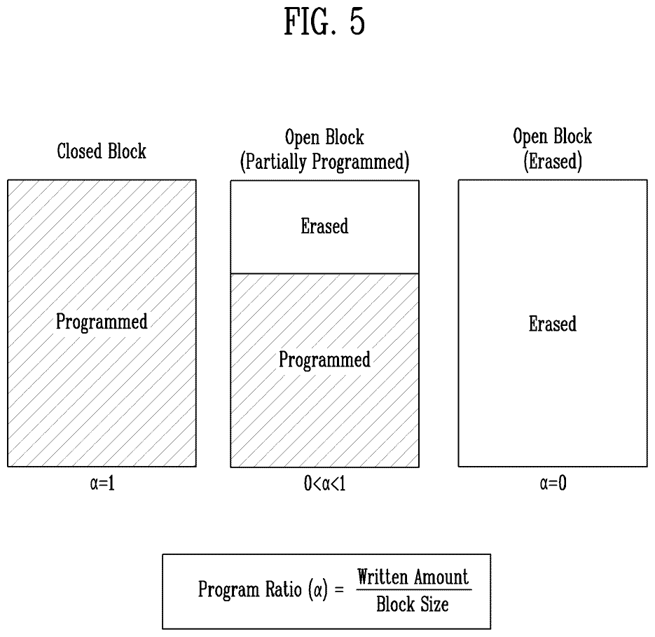

FIG. 5 is a diagram illustrating a program ratio of a memory block in accordance with an embodiment of the present disclosure.

Referring to FIG. 5, an open block may be a memory block in which data writing is possible. A closed block may be a memory block in which new data writing is impossible since data writing is completed. A program ratio α of a memory block may be a value obtained by an amount of data written to the memory block by a block size. The program ratio a may have a value between 0 and 1.

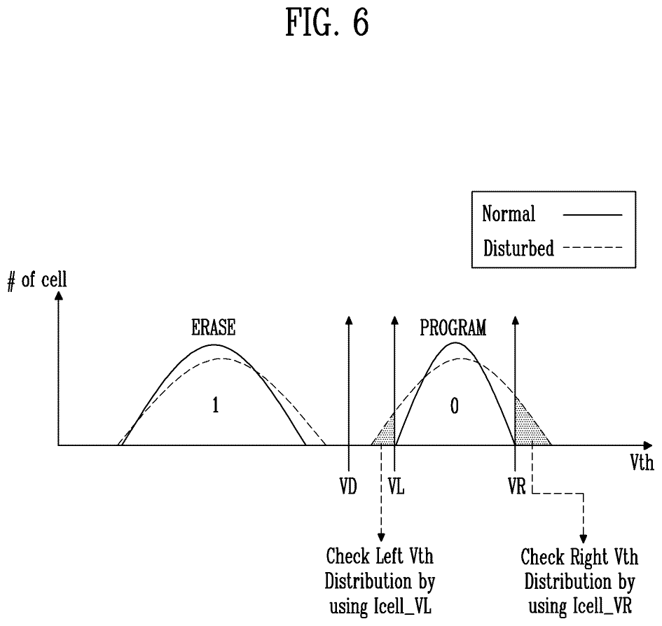

FIG. 6 is a diagram illustrating a threshold voltage distribution of memory cells in accordance with an embodiment of the present disclosure.

Referring to FIG. 6, a threshold voltage distribution of memory cells may be divided into an erase cell (or on-cell) and a program cell (or off-cell), based on a default read voltage VD. Memory cells having a threshold voltage lower than the default read voltage VD among the memory cells may be read as erase cells, and represent 1 as data. Memory cells having a threshold voltage higher than the default read voltage VD among the memory cells may be read as program cells, and represent 0 as data.

As described with reference to FIG. 4, a read operation may be performed by applying the default read voltage VD to a plurality of word lines WL1 to WLn to determine a threshold voltage distribution of a plurality of memory cells. A number of program cells among a plurality of memory cells included in a memory block may be counted based on a cell current of the read operation performed using the default read voltage VD. A program ratio of the memory block may be calculated based on the number of program cells.

As a read count of the memory block increases, read disturbance may occur, and a threshold voltage distribution width of degraded memory cells may become wider than a normal threshold voltage distribution width.

In accordance with an embodiment described with reference to FIG. 6, degraded select transistors which exceed a normal threshold voltage distribution width among a plurality of select transistors may be checked.

For example, a number of left degraded select transistors which exceed a left edge voltage VL of the normal threshold voltage distribution width may be counted based on a cell current Icell_VL of a read operation performed by applying the left edge voltage VL to a target select line among a plurality of select lines. A value of the cell current Icell_VL may further increase in a degraded threshold voltage distribution as compared with the normal threshold voltage distribution. This is because, in the case of the degraded threshold voltage distribution, a number of select transistors having a threshold voltage lower than the left edge voltage VL increases, a number of on-cells increases, and accordingly, the cell current Icell_VL is increased.

A number of right degraded select transistors which exceed a right edge voltage VR of the normal threshold voltage distribution width may be counted based on a cell current Icell_VR of a read operation performed by applying the right edge voltage VR to a target select line among the plurality of select lines. A value of the cell current Icell_VR may further increase in a degraded threshold voltage distribution as compared with the normal threshold voltage distribution. This is because, in the case of the degraded threshold voltage distribution, a number of select transistors having a threshold voltage higher than the right edge voltage VR increases, a number of off-cells increases, and accordingly, the cell current Icell_VR is decreased.

As such, how a current threshold voltage distribution has been influenced by disturbance, as compared with the normal threshold voltage distribution width, may be checked through the number of left degraded select transistors, which is measured based on the cell current Icell_VL, and the number of right degraded select transistors, which is measured based on the cell Icell_VR. In addition, in an embodiment, a remaining read count (or remaining lifespan) of the memory block, which will be described later, may be predicted according to a degree to which the current threshold voltage distribution is influenced by the disturbance.

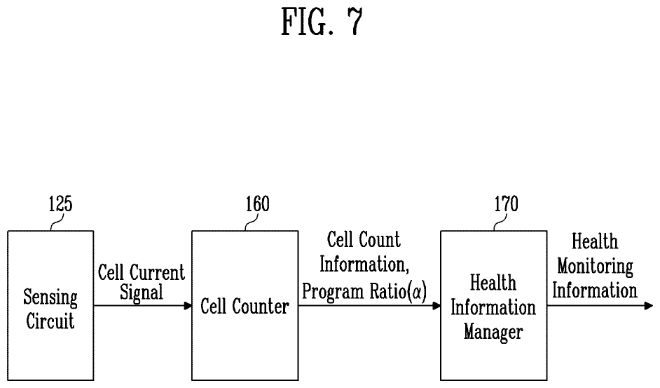

FIG. 7 is a diagram illustrating a process of generating health monitoring information in accordance with an embodiment of the present disclosure.

Referring to FIG. 7, the sensing circuit 125 may measure a cell current of memory cells in a read operation on the memory cells. The sensing circuit 125 may transfer a cell current signal as an analog signal to the cell counter 160. The sensing circuit may also measure a cell current of select transistors like the memory cells.

The cell counter 160 may convert the cell current signal as the analog signal into a digital signal, and count a number of memory cells, using the converted digital signal. The cell counter 160 may generate cell count information including the counted number of memory cells. Similarly, the cell counter 160 may count a number of degraded select transistors, and generate cell count information including the number of degraded select transistors.

The health information manager 170 may calculate a remaining read count of a memory block, based on the cell count information. Specifically, the health information manager 170 may calculate the remaining read count, using the cell count information, a program ratio of the memory block, a reference cell count corresponding to the cell current, and a remaining read count function. The remaining read count function may be a function predetermined through a test in a manufacturing process. The word “predetermined” as used herein with respect to a parameter, such as a predetermined function, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm.

The health information manager 170 may generate read reclaim information indicating that the memory block is one of a foreground read reclaim target, a background read reclaim target, and an after health monitoring target. Foreground read reclaim may be a read reclaim operation of performing an operation according to a request of the host in a priority order equal to the request of the host. Background read reclaim may be a read reclaim operation performed in a memory block in an idle period in which the operation according to the request of the host is not performed in a priority order lower than the request of the host. The after health monitoring target may be a target on which a current read reclaim operation is not performed but health monitoring is re-performed after a read count of the memory block elapses by an after read count.

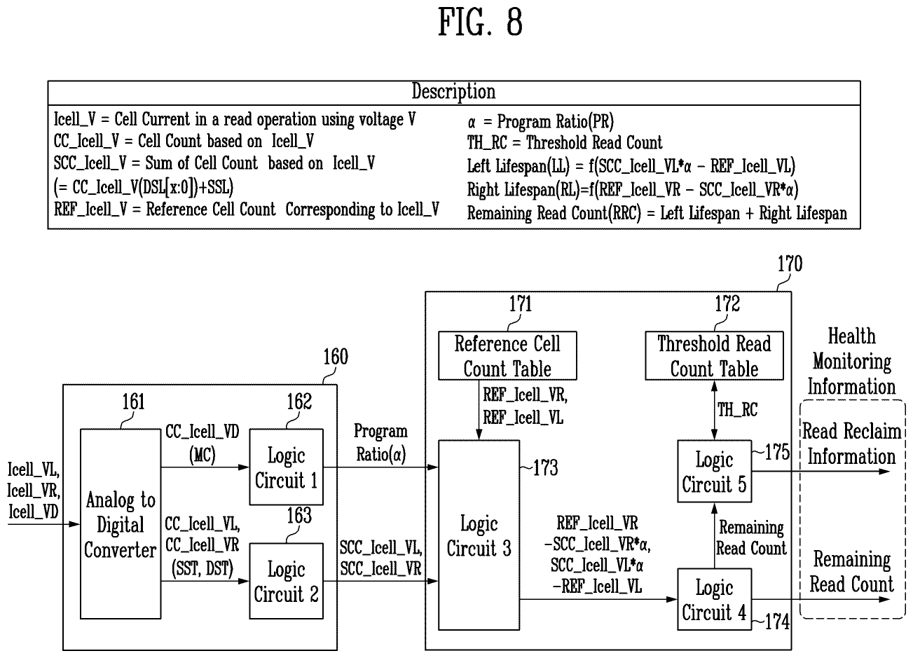

FIG. 8 is a diagram illustrating an embodiment of the process of generating the health monitoring information, which is shown in FIG. 7.

Referring to FIG. 8, the cell counter 160 may include an analog-to-digital converter 161, a first logic circuit 162 (i.e., Logic Circuit 1), and a second logic circuit 163 (i.e., Logic Circuit 2).

The analog-to-digital converter 161 may convert a cell current as an analog signal into a digital signal, and count a number of memory cells, which corresponds to the cell current.

For example, the analog-to-digital converter 161 may count a number of program cells among the plurality of memory cells, based on the cell current Icell_VD of the read operation performed on the plurality of memory cells, using the default read voltage VD described with reference to FIG. 6. A number of counted programmed cells by the analog to digital converter 161 may be CC_Icell_VD.

The analog-to-digital converter 161 may count a number of programmed cells among the plurality of memory cells, based on the cell current Icell_VD of the read operation performed on the plurality of memory cells, using the default read voltage VD described with reference to FIG. 6. The analog-to-digital converter 161 may output the number of the counted program cells CC_Icell_VD to the first logic circuit 162.

The analog-to-digital converter 161 may count a number of select transistors having a threshold voltage lower than the left edge voltage VL of the default threshold voltage distribution width described with reference to FIG. 6 among the plurality of memory cells, based on the cell current Icell_VL of the read operation performed on the plurality of select transistors, using the left edge voltage VL. The analog-to-digital converter 161 may output, to the second logic circuit 163, a number of counted left degraded select transistors CC_Icell_VL having a threshold voltage lower than the left edge voltage VL.

The analog-to-digital converter 161 may count a number of select transistors having a threshold voltage higher than the right edge voltage VR of the default threshold voltage distribution width described with reference to FIG. 6 among the plurality of memory cells, based on the cell current Icell_VR of the read operation performed on the plurality of select transistors, using the right edge voltage VR. The analog-to-digital converter 161 may output, to the second logic circuit 163, a number of counted right degraded select transistors CC_Icell_VR having a threshold voltage higher than the right edge voltage VR. The plurality of select transistors may include at least one select transistor among a plurality drain select transistors and a plurality of source select transistors.

The first logic circuit 162 may calculate a program ratio α of a memory block, based on a number of counted program cells CC_Icell_VD among a plurality of memory cells included in the memory block. The first logic circuit 162 may output the calculated program ratio α to the health information manager 170.

The second logic circuit 163 may sum the counted number of the degraded select transistors, which are received from the analog-to-digital converter 161. The second logic circuit 163 may output the summed counted number of the degraded select transistors to the health information manager 170. For example, when the plurality of drain select transistors included in the memory block are connected to a plurality of drain select lines DSL[x:0] and the plurality of source select transistors included in the memory block are connected to a source select line SSL, the second logic circuit 163 may sum a number of counted drain select transistors corresponding to each of the plurality of drain select lines DSL[x:0] and a number of counted source select transistors connected to the source select line SL. The second logic circuit 163 may output, to the health information manager 170, summed number of counted left degraded select transistors SCC_Icell_VL and right degraded select transistors SCC_Icell_VR of the degraded select transistors, which respectively correspond to the read voltages VL and VR. The cell count information shown in FIG. 7 may include the summed number of counted left degraded select transistors SCC_Icell_VL and right degraded select transistors SCC_Icell_VR of the degraded select transistors, which respectively correspond to the read voltages VL and VR.

The health information manager 170 may include a reference cell count table 171, a threshold read count table 172, a third logic circuit 173 (i.e., Logic Circuit 3), a fourth logic circuit 174 (i.e., Logic Circuit 4), and a fifth logic circuit 175 (i.e., Logic Circuit 5).

The reference cell count table 171 may include reference cell counts corresponding to a cell current for each program ratio a. For example, the reference cell count table 171 may include a reference cell count REF_Icell_VL corresponding to the cell current Icell_VL of the read operation performed on the select transistors, using the left edge voltage VL of the default threshold voltage distribution. The reference cell count REF_Icell_VL may be a number of select transistors counted as program cells, using the left edge voltage VL as a read voltage, when the select transistors have the default threshold voltage distribution. The reference cell count table 171 may include a reference cell count REF_Icell_VR corresponding to the cell current Icell_VR of the read operation performed on the select transistors, using the right edge voltage VR of the default threshold voltage distribution. The reference cell count REF_Icell_VR may be a number of select transistors counted as program cells, using the right edge voltage VR as a read voltage, when the select transistors have the default threshold voltage distribution.

The threshold read count table 172 may include a plurality of threshold read counts. The plurality of threshold read counts may be compared with a remaining read count of the memory block to determine when the memory block is a read reclaim target.

The third logic circuit 173 may calculate a first value obtained by subtracting the left reference cell count REF_Icell_VL from a value obtained by multiplying the number of counted left degraded select transistors SCC_Icell_VL and the program ratio a. The third logic circuit 173 may calculate a second value obtained by subtracting a value obtained by multiplying the number of counted right degraded select transistors SCC_Icell_VR and the program ratio α from the right reference cell count REF_Icell_VR. The third logic circuit 173 may output the calculated first value and the calculated second value to the fourth logic 174.

The fourth logic circuit 174 may calculate a remaining read count by adding values respectively obtained by substituting the first value and the second value in a function f predetermined through a test in a manufacturing process to calculate the remaining read count of the memory block. The fourth logic circuit 174 may output the calculated remaining read count of the memory block.

In FIG. 8, a left lifespan is a result obtained by substituting the first value in the predetermined function f, and may be a remaining read count calculated by considering disturbance caused by select transistors located at the left with respect to the center of a threshold voltage distribution width. A right lifespan is a result obtained by substituting the second value in the predetermined function f, and may be a remaining read count calculated by considering disturbance caused by select transistors located at the right with respect to the center of the threshold voltage distribution width. The remaining read count may be a sum of the left lifespan and the right lifespan.

The fifth logic circuit 175 may generate read reclaim information indicating that the memory block is one of a foreground read reclaim target, a background read reclaim target, and an after health monitoring target according to a result obtained by comparing the remaining read count with the plurality of threshold read counts. Specifically, when the remaining read count of the memory block is smaller than a first threshold read count, the memory block may be the foreground read reclaim target. When the remaining read count is greater than or equal to the first threshold read count and is smaller than a second threshold read count, the memory block may be the background read reclaim target. When the remaining read count is greater than or equal to the second threshold read count and is smaller than a third threshold read count, the memory block may be the after health monitoring target.

The health monitoring information may include read reclaim information and the remaining read count.

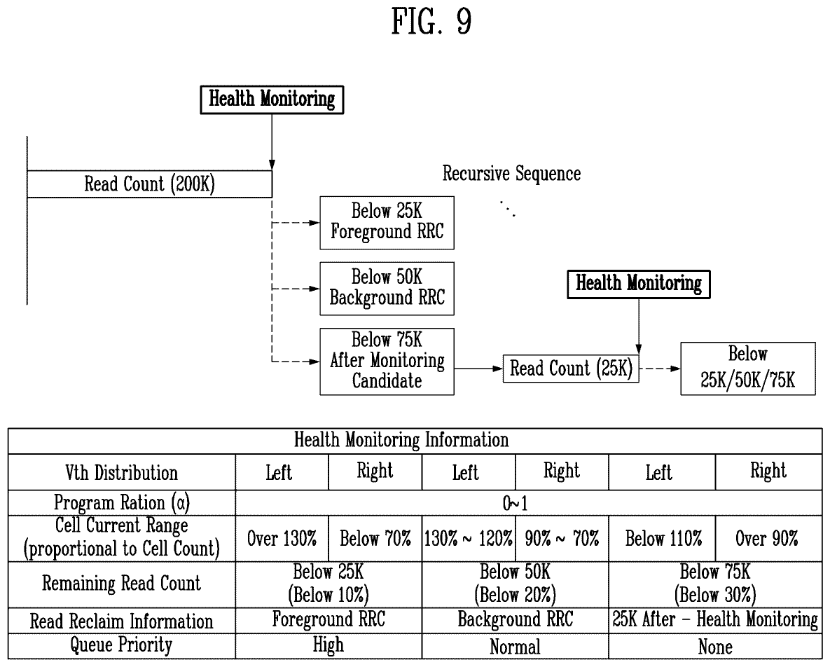

FIG. 9 is a diagram illustrating a health monitoring operation and health monitoring information in accordance with an embodiment of the present disclosure.

Referring to FIG. 9, the memory controller may provide a health monitoring count to the memory device when a read count of a memory block exceeds a health check read count. The health monitoring command may include a set feature command. The health check read count may be 200k.

The memory device may check degraded memory cells which exit out of a normal threshold voltage distribution width among memory cells included in the memory block in response to the health monitoring command. Specifically, the memory device may check degraded select transistors which exit out of the normal threshold voltage distribution width among select transistors included in the memory block. As described with reference to FIG. 6, the magnitude of a cell current in a read operation using a left edge voltage is increased as the number of left degraded select transistors increases. The magnitude of a cell current in a read operation using a right edge voltage is decreased as the number of right degraded select transistors increases.

In FIG. 9, a first threshold read count may be 25k, a second threshold read count may be 50k, and a third threshold read count may be 75k. As used herein and as shown in FIG. 9, the tilde “˜” indicates a range of numbers or percentages. [Original paragraph 116,

When the number of left degraded select transistors or the number of right degraded select transistors becomes different by 30% or more as compared with the normal threshold voltage distribution width, the memory device may determine that a remaining read count of the memory block is the first threshold read count or less, and determine that the memory block is a foreground read reclaim target.

When the number of left degraded select transistors or the number of right degraded select transistors becomes different by 20% to 30% as compared with the normal threshold voltage distribution width, the memory device may determine that the remaining read count of the memory block is the second threshold read count or less, and determine that the memory block is a background read reclaim target.

When the number of left degraded select transistors or the number of right degraded select transistors becomes different by 10% or less as compared with the normal threshold voltage distribution width, the memory device may determine that the remaining read count of the memory block is the third threshold read count or less, and determine that the memory block is an after health monitoring target.

When the memory block is determined as the after health monitoring target, the memory controller may provide the memory device with the health monitoring command after the read count of the memory block further increases by an after read count. After then, the memory device may regenerates the cell count information. The after read count may be 25k. In the above manner, a health monitoring operation on the memory block may be periodically performed.

The memory controller may provide a health monitoring information request command to the memory device, and the memory device may provide the memory controller with health monitoring information including read reclaim information in response to the health monitoring information request command. The health monitoring information request command may include a get feature command.

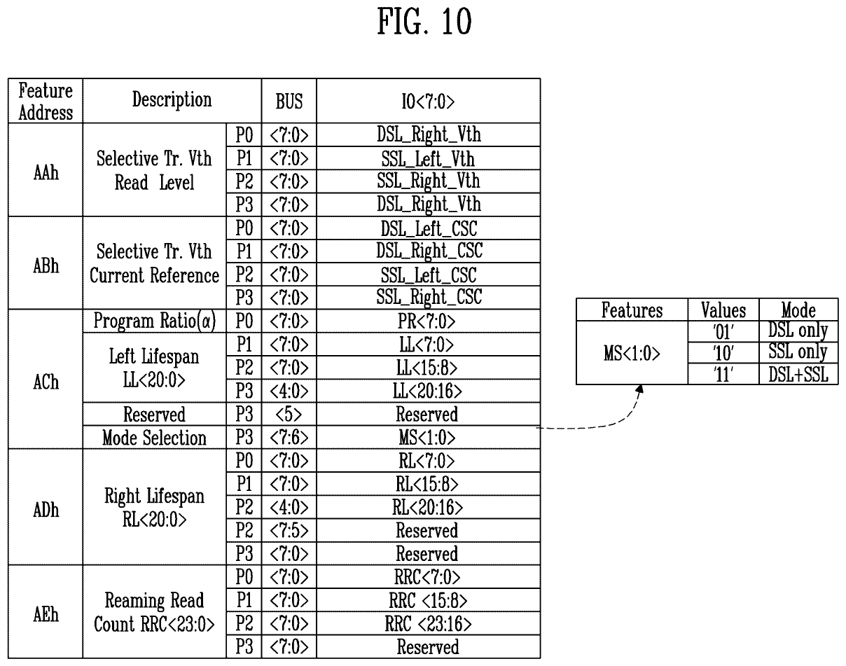

FIG. 10 is a flowchart illustrating an interface command of the memory device in accordance with an embodiment of the present disclosure.

Referring to FIGS. 8 and 10, the memory controller and the memory device may transmit/receive data corresponding to each feature address through an 8-bit bus corresponding to each of a plurality of pins P0 to P3.

When the feature address is AAh, the data may include information on a left edge voltage and a right edge voltage of the normal threshold voltage distribution width described with reference to FIG. 6 for each drain select line and each source select line.

When the feature address is ABh, the data may include information on a reference cell current corresponding to the left edge voltage of the normal threshold voltage distribution width and a reference cell current corresponding to the right edge voltage of the normal threshold voltage distribution width for each drain select line and each source select line.

When the feature address is ACh, the data may include a program ratio, a left lifespan, and a mode selection. The memory device may check a threshold voltage distribution of at least one select transistor among drain select transistors and source select transistors according to a value set in the mode selection. For example, when a mode selection value (i.e. MS<1:0>) is 01, the memory device may check only a threshold voltage distribution of drain select transistors connected to the drain select line. When the mode selection value is 10, the memory device may check only a threshold voltage distribution of source select transistors connected to the source select line. When the mode selection value is 11, the memory device may check a threshold voltage distribution of both the drain select transistors and the source select transistors.

When the feature address is ADh, the data may include information on a right lifespan.

When the feature address is AEh, the data may include information on a remaining read count of the memory block.

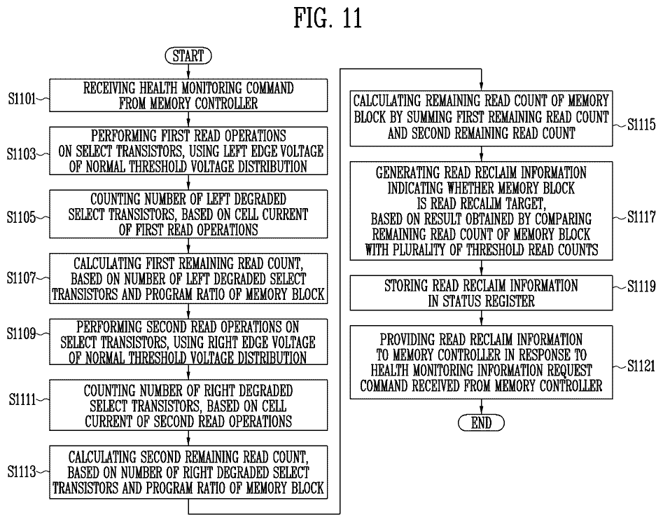

FIG. 11 is a flowchart illustrating an operation of the memory device in accordance with an embodiment of the present disclosure.

Referring to FIG. 11, in S1101, the memory device may receive a health monitoring command from the memory controller. The health monitoring command may be a command instructing the memory device to check degraded memory cells which exit out of a normal threshold voltage distribution width among memory cells included in a memory block.

In S1103, the memory device may perform first read operations on select transistors, using a left edge voltage of the normal threshold voltage distribution width. The select transistors may include at least one select transistors among the drain select transistors and source select transistor

In S1105, the memory device may count a number of left degraded select transistors, based on a cell current of the first read operations.

In S1107, the memory device may calculate a first remaining read count, based on the number of left degraded select transistors and a program ratio of the memory block.

In S1109, the memory device may perform second read operations on select transistors, using a right edge voltage of the normal threshold voltage distribution width. The select transistors may be the select transistors on which the first read operations are performed in S1103.

In S1111, the memory device may count a number of right degraded select transistors, based on a cell current of the second read operations.

In S1113, the memory device may calculate a second remaining read count, based on the number of right degraded select transistors and the program ratio of the memory block.

In S1115, the memory device may calculate a remaining read count of the memory block by summing the first remaining read count and the second remaining read count.

In S1117, the memory device may generate read reclaim information indicating whether the memory block is a read reclaim target, based on a result obtained by comparing the remaining read count of the memory block with a plurality of threshold read counts.

In S1119, the memory device may store the read reclaim information in a status register.

In S1121, the memory device may provide the read reclaim information to the memory controller in response to a health monitoring information request command received from the memory controller.

In accordance with an embodiment of the present disclosure, there can be provided a storage device for predicting a remaining lifespan of a memory block, based on a cell current of select transistors, and performing a read reclaim operation, based to the remaining lifespan, and an operating method of the storage device.

While the present disclosure has been shown and described with reference to certain examples of embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described examples of embodiments but should be determined by not only the appended claims but also the equivalents thereof.

In the above-described embodiments, all steps may be selectively performed or part of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, the examples of embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A memory device comprising:
a memory block including a plurality of select transistors and a plurality of memory cells, the plurality of select transistors connected to a plurality of select lines and the plurality of memory cells connected to a plurality of word lines;
a cell counter configured to count a number of degraded select transistors, from the plurality of select transistors, which exceed a normal threshold voltage distribution, based on a cell current of the plurality of select transistors, and generate cell count information including the number of the degraded select transistors; and
a health information manager configured to generate read reclaim information indicating whether the memory block is a read reclaim target according to a remaining read count of the memory block and a result obtained by comparing the remaining read count with a plurality of threshold read counts, based on the cell count information.

2. The memory device of claim 1,
wherein the plurality of select transistors include a plurality of drain select transistors and a plurality of source select transistors,
wherein the plurality of drain select transistors are connected to a plurality of drain select lines among the plurality of select lines, and
wherein the plurality of source select transistors are connected to a source select line among the plurality of select lines.

3. The memory device of claim 2, wherein the cell counter counts a number of degraded drain select transistors which exceed the normal threshold voltage distribution, based on a cell current of the plurality of drain select transistors, and counts a number of degraded source select transistors which exceed the normal threshold voltage distribution, based on a cell current of the plurality of source select transistors.

4. The memory device of claim 3, wherein the cell counter counts a number of degraded drain select transistors corresponding to a selected drain select line among the plurality of drain select lines, based on a cell current of drain select transistors connected to the selected drain select line, and generates the cell count information, based on a result obtained by summing the number of degraded drain select transistors respectively corresponding to the plurality of drain select lines.

5. The memory device of claim 4, wherein the cell count information includes at least one of the number of the degraded drain select transistor and the number of the degraded source select transistors.

6. The memory device of claim 1, wherein the health information manager generates read reclaim information indicating that the memory block is one of a foreground read reclaim target, a background read reclaim target, and an after health monitoring target according to a result obtained by comparing the remaining read count with the plurality of threshold read counts.

7. The memory device of claim 6, wherein the memory block is the foreground read reclaim target when the remaining read count is smaller than a first threshold read count among the plurality of threshold read counts, is the background read reclaim target when the remaining read count is greater than or equal to the first threshold read count and is smaller than a second threshold read count among the plurality of threshold read counts, and is the after health monitoring target when the remaining read count is greater than or equal to the second threshold read count and is smaller than a third threshold read count among the plurality of threshold read counts.

8. The memory device of claim 7, wherein, when the memory block is the after health monitoring target, the cell counter regenerates the cell count information after a read count of the memory block further increases by an after read count, and
wherein the health information manager updates the read reclaim information, based to the regenerated cell count information.

9. The memory device of claim 1, wherein the cell counter calculates a program ratio of the memory block, based on a cell current of a read operation performed by applying a reference read voltage for reading a program cell among a plurality of memory cells to a word line from the plurality of word lines.

10. The memory device of claim 9, wherein the health information manager calculates the remaining read count, based on a difference value between a value obtained by multiplying the number of the degraded select transistors and the program ratio and a threshold read count corresponding to the program ratio.

11. The memory device of claim 10, wherein the cell counter counts a number of left degraded select transistors among the degraded select transistors, based on a cell current of a read operation by applying a left edge voltage of the normal threshold voltage distribution to a target select line among the plurality of select lines, and counts a number of right degraded select transistors among the degraded select transistors, based on a cell current of a read operation by applying a right edge voltage of the normal threshold voltage distribution to the target select line among the plurality of select lines.

12. The memory device of claim 11, wherein the health information manager calculates a first value obtained by subtracting a left reference cell count corresponding to the program ratio from a value obtained by multiplying the number of the left degraded select transistors and the program ratio and a second value obtained by subtracting a value obtained by multiplying the number of the right degraded select transistors and the program ratio from a right reference cell count corresponding to the program ratio.

13. The memory device of claim 12, wherein the health information manager calculates a remaining read count of a memory block by adding values respectively obtained by substituting the first value and the second value in a function predetermined through a test in a manufacturing process to calculate the remaining read count.

14. A storage device comprising:
a memory device including a memory block including a plurality of select transistors connected to a plurality of select lines and a plurality of memory cells connected to a plurality of word lines; and
a memory controller configured to provide the memory device with a health monitoring command for checking degraded select transistors which exceed a normal threshold voltage distribution among the plurality of select transistors, receive, from the memory device, read reclaim information indicating whether the memory block is a read reclaim target, and control the memory device to perform a read reclaim operation on the memory block, based on the read reclaim information,
wherein the memory device counts a number of the degraded select transistors, based on a cell current of the plurality of select transistors in response to the health monitoring command, calculates a remaining read count of the memory block, based on the number of the degraded select transistors, and generates the read reclaim information according to a result obtained by comparing the remaining read count with a plurality of threshold read counts.

15. The storage device of claim 14, wherein the memory device stores the read reclaim information in a status register in response to the health monitoring command, and provides the read reclaim information to the memory controller in response to a health monitoring information request command received from the memory controller,
wherein the health monitoring command includes a set feature command, and
wherein the health monitoring information request command includes a get feature command.

16. The storage device of claim 14, wherein the read reclaim information indicates that the memory block is one of a foreground read reclaim target, a background read reclaim target, and an after health monitoring target according to a result obtained by comparing the remaining read count with the plurality of threshold read counts.

17. The storage device of claim 16, wherein the memory controller provides the health monitoring command to the memory device when a read count of the memory block exceeds a health check read count, and provides the health monitoring command to the memory device after the read count of the memory block further increases by an after read count, when the memory block is the after health monitoring target.

18. The storage device of claim 14, wherein the plurality of select transistors include a plurality of drain select transistors connected to a plurality of drain select lines among the plurality of select lines and a plurality of source select transistors connected to a source select line among the plurality of select lines.

19. The storage device of claim 18, wherein the memory device counts a number of degraded drain select transistors corresponding to a selected drain select line among the plurality of drain select lines, based on a cell current of drain select transistors connected to the selected drain select line, and generates the cell count information, based on a result obtained by summing numbers of degraded drain select transistors respectively corresponding to the plurality of drain select lines.

20. The storage device of claim 19, wherein the health monitoring command instructs the memory device to count at least one of the number of the degraded drain select transistors and the number of the degraded source select transistors.
